(19) United States
(12) Patent Application Publication
(10) Pub. No.: US 2021/0047722 A1
(43) Pub. Date: Feb. 18, 2021

(54) METHOD FOR COATING THERMAL/ENVIRONMENTAL BARRIER COATING

(71) Applicant: Guangdong Institute of New Materials, Guangdong (CN)

(72) Inventors: Xiaofeng Zhang, Guangdong (CN); Chao Wang, Guangdong (CN); Chunming Deng, Guangdong (CN); Min Liu, Guangdong (CN); Ziqian Deng, Guangdong (CN); Shaopeng Niu, Guangdong (CN); Jie Mao, Guangdong (CN); Changguang Deng, Guangdong (CN); Kesong Zhou, Guangdong (CN)

(21) Appl. No.: 16/734,847

(22) Filed: Jan. 6, 2020

(30) Foreign Application Priority Data
Aug. 13, 2019 (CN) CN 201910744227.X

(51) Int. Cl. C23C 14/18; C23C 14/35; C23C 14/02; C23C 14/58; C23C 28/00; C23C 14/28

(52) U.S. Cl. CPC C23C 14/18; C23C 14/35; C23C 14/28; C23C 14/5806; C23C 28/324; C23C 14/024

(57) ABSTRACT

The present disclosure discloses a method for coating an environmental barrier coating, comprising: coating an aluminum film layer on a surface of a rare earth silicate ceramic layer, and heat treating the aluminum film layer to form a rare earth aluminate phase at least in pores of a side of the rare earth silicate ceramic layer facing the aluminum film layer. An environmental barrier coating prepared by the above method is also disclosed.

### CROSS-REFERENCE TO RELATED APPLICATIONS

The present application claims priority to Chinese Patent Application No. 201910744227.X, filed with the Chinese Patent Office on Aug. 13, 2019, entitled “Environmental Barrier Coating, Coating method and Application thereof”, which is incorporated herein by reference in its entirety.

### TECHNICAL FIELD

The present disclosure relates to the technical field of the surface treatment of ceramic coatings, and in particular, to a method for coating a thermal/environmental barrier coating.

### BACKGROUND ART

The development of a new generation of aero-engine with high thrust-weight ratio will inevitably lead to an increase in the temperature of fuel gas in the aero-engine, which in turn will increase the surface temperature of the hot-end components of the high-pressure turbine. The surface temperature of the hot-end components of the aero-engine with high thrust-weight ratio will reach above 1400° C., far exceeding the temperature range that the existing high-temperature alloy materials can withstand. SiC ceramic matrix composites have the characteristics of high temperature resistance (which long-term use temperature is up to 1650° C.), low density, high strength, high modulus, oxidation resistance, ablation resistance, insensitivity to cracks and the like, which have become the most promising thermal structural material that can replace the high-temperature alloy. This material can greatly reduce the weight of aero-engine, reduce the amount of fuel gas and cooling air, and improve the thrust-weight ratio. For the aero-engine, SiC ceramic matrix composite is mainly used in hot-end components, such as exhaust nozzles, combustion chambers/afterburners, turbines and the like, the material can increase the operating temperature to 200˜500° C. and reduce the structure weight by 30%˜50%, which has become one of the key thermal structural materials for aero-engine to increase the thrust-weight ratio. Under the working environment of the engine, many factors, such as high temperature, corrosive media, fuel gas scour, and complex stress environment, interact with each other, and the surface stability of SiC ceramic matrix composite is deteriorated sharply, which has become one of the main factors restricting its application to hot-end components of aero-engine. The environmental barrier coating (EBC) can effectively solve this problem and become the key technology for the application of SiC ceramic matrix composite in hot-end components of aero-engines with high thrust-weight ratio.

The function of environmental barrier coating is to protect the basis material in the harsh environment of the engine, and prevent or reduce the influence of the engine environment on the performance of high-temperature structural materials. To achieve this purpose, the environmental barrier coating material itself must have the following characteristics: (1) the coating material should have a relatively high melting point as the coating material directly contacts the external high-temperature environment; (2) there should be a good mechanical bonding force between the coating material system and the basis material to ensure that no peeling will occur between the coating system and the substrate (basis) and among the layers inside the coating system; (3) the coating material should have good surface stability and relatively low oxygen permeability to prevent it from reacting with the ambient gas and to prevent oxygen from contacting the basis material as much as possible; (4) the coating material should have a similar coefficient of thermal expansion (CTE) as the basis material, if the coefficients of thermal expansion are significantly different, then stress will be generated during use, which will cause delamination and cracks; (5) the phase change of the coating material under high temperature condition cannot occur, as the phase change generally causes a volume change, which in turn causes the coating to crack or even peel; (6) the coating material should have a better chemical stability and corrosion resistance, which avoids the formation of unstable phases and can resist the corrosion by harsh environment of the engine; (7) the coating should be dense, uniform and with few defects, under the premise of ensuring the ability to resist oxidation and corrosion, the density should be as low as possible without affecting the overall performance of the basis material.

Based on the characteristics that the environmental barrier coating material must have, NASA carried out research on environmental barrier coatings in the 1960s. So far, the research on environmental barrier coating materials has mainly gone through the following stages. Early researches on environmental barrier coatings mainly focused on improving the performance of resistance to molten salt corrosion of the coatings. Compared with non-oxide ceramics, oxide ceramics have better high-temperature corrosion resistance and long-term stability, and are the first choice for environmental barrier coating materials for silicon-based non-oxide ceramic surface. Mullite (3Al₂O₃—2SiO₂) first entered people's field of vision as it has a similar coefficient of thermal expansion as silicon-based ceramic materials, good chemical compatibility, and excellent corrosion resistance. The first-generation environmental barrier coating mainly refers to the mullite coating deposited on the surface of silicon-based ceramics by using the air plasma spraying (APS) method. The main problem of the early first-generation mullite environmental barrier coatings was that the coatings would produce more cracks during use, so that the corrosive substances could infiltrate along the cracks and contact the substrate, causing damage to the substrate. The research team of NASA's Glen Research Center analyzed the mechanism of crack generation in environmental barrier coatings and found that when the mullite environmental barrier coatings were prepared by using the conventional APS method, due to the relatively large temperature drop rate during the curing and coagulation process of mullite, more metastable mullite was present in the coating. During the use of the coating at a relatively high temperature, such metastable mullite was converted into stable mullite with lower free energy. The densities of the two kinds of mullite are different, and thermal stress will be generated in the process of conversion, which will cause cracks. In response to the shortcomings of early environmental barrier coatings, NASA's research team improved the process of preparing coatings by the APS method. In the process of preparing the mullite environmental barrier coating, the substrate was heated to increase the substrate temperature and reduce the temperature drop during the curing and coagulation processes of the coating, thereby effectively controlling the metastable mullite content in the coating. Its research showed that the environmental barrier coating prepared by using the improved APS method had a significant reduction in the number of cracks generated during use, compared to the environmental barrier coating prepared by using the conventional APS method. The adhesive force of the improved mullite environmental barrier coating was enhanced, and cracks in the coating were effectively controlled, but the surface stability of the silicon-based non-oxide ceramic with the mullite environmental barrier coating was still insufficient. In the 1990s, with the recognition by people of the mechanism of the formation of volatile Si(OH)₄ by the reaction of SiO₂ and water vapor, the focus of research on environmental barrier coatings was shifted from improving the performance of resistance to molten salt corrosion of ceramic substrates to improving its ability to resist water vapor erosion, which required that the coating surface must first have the ability to resist water vapor erosion. Mullite has a relatively high SiO₂ activity (approximately 0.4). As mentioned earlier, SiO₂ reacts with water vapor to form volatile Si(OH)₄, which is carried away by the airflow moving at a high speed, so that only loosened Al₂O₃ layer was left on the coating surface, and the peeling of the loosened Al₂O₃ layer causes the coating to fail. Therefore, the mullite environmental barrier coating has a poor ability to resist water vapor erosion. A good environmental barrier coating should also have a ceramic surface layer on the outer surface of the mullite coating. Yttria-Stabilized Zirconia (YSZ) was first tried because of its good application in thermal barrier coatings in engine environment. The environmental barrier coating of mullite +YSZ system significantly reduced the volatilization of SiO₂ during the initial service, but the durability of this protective effect was insufficient. When the coating was used in an environment containing water vapor at 1300° C. for about 100 hours, the coating would undergo accelerated oxidation failure. The analysis showed that such accelerated oxidation failure has a lot to do with the cracks generated during the service process of the coating. The coefficient of thermal expansion of YSZ is relatively high, which is about twice that of mullite. The generation of thermal stress is unavoidable in the process of cold and thermal cycles, and thus the cracks are induced. When cracks penetrate the entire YSZ layer and mullite layer, water vapor will spread along the cracks and contact the substrate, accelerating the oxidation of the substrate. The first-generation environmental barrier coatings were far from being able to be applied in the engine environment due to the insufficient long-term stability of the coating materials and the formation of cracks during use.

NASA developed the second-generation environmental barrier coating based on the first-generation environmental barrier coating. The second-generation environmental barrier coating used mullite as an intermediate layer, and used BSAS (BaO₁₋ₓ—SrOₓ—Al₂O₃—SiO₂, 0≤x<1) as the surface layer of the environmental barrier coating. Compared with mullite, BSAS has a lower SiO₂ activity (<0.1), which reduces the volatilization of the coating in the engine environment. At the same time, BSAS also has a lower coefficient of thermal expansion and elastic modulus, which matches well with mullite, so that the thermal stress generated by the coating in the process of thermal cycle is relatively small, which suppresses the occurrence of cracks. Another improvement of the second-generation environmental barrier coating over the first-generation environmental barrier coating is to first apply a layer of silicon on the surface of the silicon-based ceramic before coating the mullite layer. The presence of the silicon layer enhances the bonding force between the coating and the substrate. The most significant advantage of the second-generation environmental barrier coating over the first-generation environmental barrier coating is that it greatly improves the durability of the coating's protection to the substrate, and has been well applied in practice. The SiC whisker-reinforced SiC ceramics coated with the second-generation environmental barrier coating are used in the lining of turbine engine shell (which maximum temperature is 1250° C.), and the service life is more than three times longer than without the environmental barrier coating. The disadvantage of the second-generation environmental barrier coatings is their lower maximum use temperature. At higher operating temperatures, although the SiO₂ activity in BSAS is lower than that of mullite, the surface stability of the coating still cannot meet the requirements of engine design. At 1400° C., in a fuel gas environment with a total pressure of 6 standard atmospheres and a gas flow rate of 24 m/s, the degradation size range of BSAS coating for 1000 h is about 70 μm. And BSAS has poor chemical compatibility with SiO₂ at high temperatures. At 1200° C., BSAS reacts with SiO₂ to form a glass phase. At a higher temperature, the glass phase forms faster. Such glass phase has a relatively low molten temperature zone of about 1300° C. The presence of the glass phase reduces the bonding force of the coating, which may cause early failure of the coating. Some scholars believed that the maximum temperature for ensuring that BSAS can work safely as an environmental barrier coating of a surface layer for more than 1000 h is between 1300° C. and 1400° C. The maximum temperature at which BSAS can work stably as an environmental barrier coating of the surface layer showed that the potential of silicon-based ceramics is obviously not fully tapped. NASA's goal was to prepare an environmental barrier coating which can achieve that the surface is able to withstand 1482° C. and the interface temperature of the coating and substrate can be controlled below 1316° C. Therefore, the search for a surface layer of environmental barrier coating that can be used at higher temperatures is still continuing. Such coating surface should have a lower vapor pressure in the working environment of the engine at 1482° C., and at the same time, it should better match thermophysical properties of mullite and have better chemical compatibility with mullite in the intermediate layer at 1400° C. or higher temperatures.

Based on the shortcomings of the second-generation EBC, researchers are conducting research on third-generation environmental barrier coatings. Rare earth silicates have lower SiO₂ activity than BSAS, and are less volatile than BSAS in the working environment of aero-engine, and are candidate materials for surface layer of environmental barrier coating used at higher temperatures that may replace BSAS. Among the rare earth silicates, Lu₂SiO₅, Sc₂SiO₅ and Yb₂SiO₅, etc. have no phase change in the operating temperature range of the aero-engine, which meets the requirements of environmental barrier coatings for phase structure stability. The rare earth silicate itself does not bond well with the silicon-based ceramics and cannot be directly coated on the surface of the silicon-based ceramics, but a layer of mullite needs to be coated first as an intermediate layer, therefore, the rare earth silicate to be used as the material of the surface layer of environmental barrier coating must also meet the chemical compatibility requirement with the intermediate mullite layer. Lu₂Si₂O₇, Lu₂SiO₅ and Yb₂SiO₅, etc. have relatively good chemical compatibility with mullite and will not form intermediate phase. Summarizing the above analysis, Lu₂Si₂O₇, Lu₂SiO₅ and Yb₂SiO₅ are better than BSAS in terms of surface stability in the engine environment and chemical compatibility with the intermediate layer, therefore, it is suitable as the material of the surface layer of environmental barrier coating at higher temperatures. At present, the service performance and service time of these rare earth silicate environmental barrier coatings need to be further improved.

In view of this, the present disclosure is hereby proposed.

### SUMMARY

In a first aspect, the embodiments of the present disclosure provide a method for coating an environmental barrier coating, comprising:

coating an aluminum film layer on a surface of a rare earth silicate ceramic layer formed by thermal spraying; and

heat treating the aluminum film layer to form a rare earth aluminate phase at least in pores of a side of the rare earth silicate ceramic layer facing the aluminum film layer.

In a second aspect, the embodiments of the present disclosure provide an environmental barrier coating, which is obtained by coating by using the method for coating an environmental barrier coating according to any one of the foregoing embodiments.

### BRIEF DESCRIPTION OF DRAWINGS

In order to more clearly illustrate technical solutions of embodiments of the present disclosure, drawings required for use in the embodiments will be described briefly below. It should be understood that the following drawings are merely illustrative of some embodiments of the present disclosure, and therefore should not be considered as limitation on the scope. It will be understood by those of ordinary skill in the art that other related drawings can also be obtained from these drawings without any inventive effort.

FIG. 1 is an SEM image of a cutting plane of a coating obtained after the aluminum film is coated and before the heat treatment is performed in the process of preparing the environmental barrier coating in an embodiment;

FIG. 2 is an SEM image of a cutting plane of the environmental barrier coating prepared in the embodiment.

### DETAILED DESCRIPTION OF EMBODIMENTS

In order to make the objects, technical solutions and advantages of the embodiments of the present disclosure clearer, the technical solutions in the embodiments of the present disclosure will be described clearly and completely below. If no specific conditions are specified in the embodiments, they are carried out under normal conditions or conditions recommended by manufacturers. If the manufacturers of reagents or instruments used are not specified, the reagents or instruments are conventional products commercially available.

The present disclosure provides an environmental barrier coating and a coating method thereof, which are intended to further improve the service performance and service life of an environmental barrier coating using a rare earth silicate ceramic layer as an isolation layer.

This disclosure is implemented as follows.

In a first aspect, the embodiments of the present disclosure provide a method for coating an environmental barrier coating, comprising:

coating an aluminum film layer on a surface of a rare earth silicate ceramic layer;

heat treating the aluminum film layer to form a rare earth aluminate phase at least in pores of a side of the rare earth silicate ceramic layer facing the aluminum film layer.

In an optional embodiment, the aluminum film layer is heat-treated to form a rare earth aluminate phase in the pores on the side of the rare earth silicate ceramic layer facing the aluminum film layer, and to form a rare earth aluminate phase layer on the side of the rare earth silicate ceramic layer facing the aluminum film layer.

In an optional embodiment, the thickness of the aluminum film layer is 2˜5 μm.

In an optional embodiment, the method for spraying the aluminum film layer is magnetron sputtering method.

In an optional embodiment, the operating parameters of the magnetron sputtering method are as follows: a magnetron target current of 3˜6 A and a bias voltage of 150˜250 V.

In an optional embodiment, the rare earth silicate ceramic layer includes Lu₂Si₂O₇, Lu₂SiO₅, Yb₂SiO₅ and Yb₂SiO₅ ceramic layers.

In an optional embodiment, the rare earth silicate ceramic layer is a Yb₂SiO₅ ceramic layer, and a Yb₃Al₅O₁₂ coating is formed after heat treating the surface on which the aluminum film layer is deposited.

In an optional embodiment, the heat treatment is performed by holding at a temperature of 700˜800° C. for 2˜4 h, and then raising the temperature to 1300˜1350° C. and holding for 20˜24 h.

In an optional embodiment, the heat treatment is a vacuum heat treatment in which the oxygen partial pressure is less than 2×10⁻³ Pa.

In an optional embodiment, the temperature is raised at a rate of 5˜30° C./min.

In an optional embodiment, before spraying an aluminum film layer on the surface of the Yb₂SiO₅ ceramic layer, the method further comprises:

coating a rare earth silicate ceramic layer on a surface of a mullite layer.

In an optional embodiment, the surface of the mullite layer is coated with the rare earth silicate ceramic layer by using air plasma spraying or plasma spraying-physical vapor deposition method;

In an optional embodiment, the mullite layer has a thickness of 50˜80 μm; and the rare earth silicate ceramic layer has a thickness of 80˜100 μm.

In an optional embodiment, before coating the rare earth silicate ceramic layer on the surface of the mullite layer, the method further comprises: coating the mullite layer on the surface of a silicon layer.

In an optional embodiment, the thickness of the silicon layer is 40˜60 μm;

In an optional embodiment, the surface of the silicon layer is coated with a mullite layer by using air plasma spraying or plasma spraying-physical vapor deposition method.

In an optional embodiment, before coating the mullite layer on the surface of the silicon layer, the method further comprises: coating the silicon layer on a surface of a substrate; and in an optional embodiment, the surface of the substrate is coated with a silicon layer by using air plasma spraying or plasma spraying-physical vapor deposition method.

In an optional embodiment, the substrate is a silicon carbide-based composite substrate.

In a second aspect, the embodiments of the present disclosure provide an environmental barrier coating, which is obtained by using the method for coating an environmental barrier coating according to any one of the foregoing embodiments.

In a third aspect, the embodiments of the present disclosure provide an application of the environmental barrier coating as described in the foregoing embodiments in the aerospace field.

The present disclosure has the following beneficial effects:

For the method for coating an environmental barrier coating obtained by the present disclosure through the above design, since an aluminum film layer is provided on the surface of the rare earth silicate and then heat treatment is performed, molten aluminum enters the pores on the surface of the rare earth silicate ceramic layer to fill the pores, and the molten aluminum reacts with the rare earth oxide and silicon dioxide to form a more dense and water-resistant rare earth aluminate phase, with the rare earth oxide and silicon dioxide generated by the decomposition of the rare earth silicate ceramic layer under the thermal environment. The present disclosure effectively improves the service performance of the environmental barrier coating and prolongs the service time thereof.

For the environmental barrier coating obtained by the present disclosure through the above design, since it is prepared by using the method provided by the present disclosure, it has good service performance and long service time. When used in the aerospace field, it can significantly improve the service performance and service life of the aerospace equipment.

The environmental barrier coating, the coating method and application thereof provided by the embodiments of the present disclosure will be specifically described below.

The inventors have discovered that the main reasons why the performance of existing rare earth silicate environmental barrier coatings needs to be further improved are as follows:

in the process of forming the rare earth silicate environmental barrier coating by coating, the rare earth silicate is easily decomposed into the rare earth oxide and SiO₂ during the thermal spraying deposition process, and these two substances generated by the decomposition have relatively low water-oxygen corrosion resistance; when preparing the environmental barrier coatings by thermal spraying, due to the thermal effect, there are micro-cracks on the coating surface to varying degrees, and these micro-cracks make it easy for the water and oxygen channels to form during the service process of coatings, thereby leading to early failure of the coatings; and the cracks will be formed in the process of thermal cycle, thereby making it difficult to further increase the service life of rare earth element coatings.

Method for coating an environmental barrier coating, comprises:

S1. sequentially providing a silicon layer, a mullite layer, and a rare earth silicate ceramic layer on the surface of the substrate.

The silicon layer, the mullite layer, and the rare earth silicate ceramic layer were prepared on the surface of the silicon carbide-based composite by a thermal spraying method. The thermal spraying method may be air plasma spraying or plasma spraying-physical vapor deposition method.

The silicon layer is used as a bonding layer, which firmly bonds the silicon carbide-based composite, used as a substrate, to the mullite.

The mullite has a coefficient of thermal expansion similar to that of silicon-based ceramic materials, good chemical compatibility with the silicon-based ceramic materials, and excellent corrosion resistance. Therefore, the mullite was used as the intermediate layer.

Rare earth silicates have better surface stability. The coating obtained by sequentially providing a silicon layer, a mullite layer, and a rare earth silicate layer is an environmental coating that is widely used and has better performance in the prior art.

A common air plasma spraying or plasma spraying-physical vapor deposition method is used to sequentially form a silicon layer, a mullite layer, and a rare earth silicate ceramic layer on the surface of the substrate. It should be noted that the method for providing the above coating is not limited to the air plasma spraying or plasma spraying-physical vapor deposition method, and other existing methods for providing barrier coatings are also applicable.

However, rare earth silicate is generally prepared by a solid-phase reaction sintering method, i.e., is obtained by a sintering reaction of the rare earth oxide and SiO₂ at a high temperature. During the spraying process, the temperature of the local plasma is much higher than its melting point, which leads to the decomposition of part of rare earth silicate. Although the subsequent heat treatment for the coating causes the decomposed products to react again to form rare earth silicate, the decomposed products could not react completely, and there were still some residual oxidation products, which react with water vapor under a high-temperature water-oxygen environment to form compounds to evaporate, causing the coating to have a porous structure and produce cracks in the process of thermal cycle, which destroys the service performance of the coating.

The rare earth silicate referred to in the present disclosure is preferably a rare earth silicate commonly used in environmental barrier coatings, and is specifically selected from Lu₂Si₂O₇, Lu₂SiO₅ and Yb₂SiO₅.

In order to overcome the defects caused by the preparation process of the rare earth silicate ceramic layer and further improve the performance of the environmental barrier coating, the following operations were performed on the surface of the rare earth silicate ceramic layer:

S2. coating an aluminum film layer on a surface of a rare earth silicate ceramic layer.

After the rare earth silicate ceramic layer is provided, an aluminum film layer is coated on its surface by using a magnetron sputtering method.

Specifically, in order to make the coating coated uniformly and firmly, the operating parameters of the magnetron sputtering method are as follows: a magnetron target current of 3˜6 A, and a bias voltage of 150˜250 V.

S3. heat treating the aluminum film layer to form a rare earth aluminate phase at least in pores of a side of the rare earth silicate ceramic layer facing the aluminum film layer.

There are certain micro-cracks on the surface of the rare earth silicate ceramic layer. Under the heat treatment, the molten aluminum penetrates into the coating and seals the coating cracks near the surface. In addition, the Al film fusion-covering on the surface of the environmental barrier coating and the Al infiltrated in the cracks will react with the rare earth oxide phase and the SiO₂ phase in the environmental barrier coating. The molten Al first reacts with SiO₂ to form the Al₂O₃ phase, and then Al₂O₃ phase continues to react with the rare earth oxide to form a rare earth aluminate phase. Through the above steps, rare earth aluminate phase is obtained at least in the pores of the surface of the rare earth silicate coating, and such rare earth aluminate phase is denser and has water and oxygen corrosion resistance.

Preferably, the heat treatment conditions are reasonably adjusted to form a rare earth aluminate phase in the pores on the side of the rare earth silicate ceramic layer facing the aluminum film layer, and to form a rare earth aluminate phase layer on the side of the rare earth silicate ceramic layer facing the aluminum film layer. In addition to forming the rare earth aluminate phase in the pores, rare earth aluminate phase layer, which is dense and has water and oxygen corrosion resistance, is also formed on the surface of the rare earth silicate ceramic layer to further improve the performance of the environmental barrier coating.

Preferably, in the preferred embodiments of the present disclosure, the rare earth silicate is preferably Yb₂SiO₅, and a Yb₃Al₅O₁₂ coating is formed after heat treating the surface on which the aluminum film layer is deposited.

Yb₃Al₅O₁₂ has a regular dodecahedron garnet-type crystal structure and is generally crystallized in an isometric system. It has a good thermal compatibility with Yb₂SiO₅ (Yb₃Al₅O₁₂ has a coefficient of thermal expansion of 7.5×10⁻⁶ K⁻¹ and Yb₂SiO₅ has a coefficient of thermal expansion of 7˜8×10⁻⁶ K⁻¹), and meanwhile, has relatively high strength and fracture toughness and low heat conductivity coefficient (theoretical heat conductivity coefficient being ˜1.22 w/m·k). Yb₃Al₅O₁₂ is limited by its material characteristics, and it is easy to generate relatively large stress cracks in the process of thermal spraying, which causes relatively large defects in the coating. However, in the present disclosure, Yb₃Al₅O₁₂ is synthesized in situ by performing vacuum heat treatment on an aluminum film layer used as a reaction material and the decomposition products of the Yb₂SiO₅ ceramic layer, which not only effectively solves the defects of the original Yb₂SiO₅ ceramic layer generated during the spraying process, but also avoids the relatively large stress cracks caused by directly forming the Yb₃Al₅O₁₂ protective layer in the process of preparation, and which not only can improve the service performance and service time of the environmental barrier coating on the basis of the existing environmental barrier coating using Yb₂SiO₅ ceramic layer as the surface layer, but also can make Yb₃Al₅O₁₂ play an advantage in the field of high temperature protection.

Preferably, in order to ensure that the overall performance of the prepared environmental barrier coating is better, the thickness of the silicon layer is 40˜60 μm, the thickness of the mullite layer is 50˜80 μm, and the thickness of the Yb₂SiO₅ ceramic layer is 80˜100 μm.

Preferably, in order to ensure that the thickness of the prepared Yb₃Al₅O₁₂ coating is more suitable for environmental barrier coatings, and to ensure that sufficient molten aluminum can penetrate into the cracks and pores of the Yb₂SiO₅ ceramic layer under a vacuum heat treatment, the thickness of the aluminum film layer is 2˜5 μm.

Preferably, the melting point of pure aluminum is known to be about 667° C., in order to ensure that the Yb₃Al₅O₁₂ phase can be obtained by heat treatment, the vacuum heat treatment is performed by holding at 700˜800° C. for 2˜4 h, and then raising the temperature to 1300˜1350° C. and holding for 20˜24 h. The temperature is maintained at 700-800° C. for 2-4 h to make the Al film remolten and fully penetrate into the coating pores and spread evenly on the coating (if the time is too short, Al cannot fully penetrate into the pores and spread). At the same time, Al will also undergo the preoxidation reaction to form Al₂O₃. It is then heated to the temperature (1300-1350° C.) for the reaction between Al₂O₃ and Yb₂O₃, so that Al₂O₃ and Yb₂O₃ react in situ to generate Yb₃Al₅O₁₂, making the Yb₃Al₅O₁₂ protective layer cover the coating uniformly.

Preferably, in order to avoid air interference reaction, the heat treatment is a vacuum heat treatment, and the oxygen partial pressure is less than 2×10⁻³ Pa. Of course, in other embodiments of the present disclosure, the heat treatment may also be performed in an inert gas atmosphere, which can also achieve the effect of preventing air from participating in the reaction.

More preferably, the temperature is raised at a rate of 5˜30° C./min. The temperature raised rate is guaranteed within a certain range, which not only ensures the heating efficiency, but also avoids relatively large thermal stress generated in the coating caused by the too fast rate, which stress may introduce defects and damage the mechanical properties of the original coating.

The environmental barrier coating provided by the embodiments of the present disclosure is obtained by coating by using the method for coating an environmental barrier coating provided by the embodiments of the present disclosure. The coating has good resistance to water and oxygen corrosion and long service life. The coating is suitable for the aerospace field. When the coating is used as the coating of an aero-engine, the service life of the aero-engine can be greatly prolonged.

The features and performances of the present disclosure will be further described in detail below in combination with the embodiments.

### Embodiment 1

The method for coating an environmental barrier coating provided by this embodiment includes the following operating steps:

preparing a Si coating, a mullite coating, and a Yb₂SiO₅ coating on the surface of silicon carbide-based composite substrate by using air plasma spraying, with the coatings successively having thicknesses of 50 μm, 50 μm and 80 μm;

preparing an aluminum film layer with a thickness of 3μm on the surface of the Yb₂SiO₅ coating by using the magnetron sputtering, wherein the conditions of the magnetron sputtering are as follows: a magnetron target current of 3 A and a bias voltage of 150 V;

heat treating the Yb₂SiO₅ coating deposited with the aluminum film layer, wherein the conditions of heat treatment are as follows: 800° C. kept for 2 h, 1300° C. kept for 24 h, a temperature raising rate of 5° C./min, and a vacuum oxygen partial pressure less than 2×10⁻³ P; and

cooling to a room temperature, to obtain the environmental barrier coating on the surface of the substrate.

### Embodiment 2

The method for coating an environmental barrier coating provided by this embodiment includes the following operating steps:

preparing a Si coating, a mullite coating, and a Yb₂SiO₅ coating on the surface of silicon carbide-based composite substrate by using plasma spraying-physical vapor deposition, with the coatings successively having thicknesses of 50 μm, 50 μm and 80 μm;

preparing an aluminum film layer with a thickness of 3 μm on the surface of the Yb₂SiO₅ coating by using the magnetron sputtering, wherein the conditions of the magnetron sputtering are as follows: a magnetron target current of 3 A and a bias voltage of 150 V;

heat treating the Yb₂SiO₅ coating deposited with the aluminum film layer, wherein the conditions of heat treatment are as follows: 700° C. kept for 2 h, 1300° C. kept for 24 h, a temperature raising rate of 10° C./min, and a vacuum oxygen partial pressure less than 2×10⁻³ Pa; and

cooling to a room temperature, to obtain the environmental barrier coating on the surface of the substrate.

### Embodiment 3

The method for coating an environmental barrier coating provided by this embodiment includes the following operating steps:

preparing a Si coating, a mullite coating, and a Yb₂SiO₅ coating on the surface of silicon carbide-based composite substrate by using plasma spraying-physical vapor deposition, with the coatings successively having thicknesses of 50 μm, 50 μm and 80 μm;

preparing an aluminum film layer with a thickness of 2 μm on the surface of the Yb₂SiO₅ coating by using the magnetron sputtering, wherein the conditions of the magnetron sputtering are as follows: a magnetron target current of 3 A and a bias voltage of 150 V;

heat treating the Yb₂SiO₅ coating deposited with the aluminum film layer, wherein the conditions of heat treatment are as follows: 700° C. kept for 2 h, 1350° C. kept for 20 h, a temperature raising rate of 10° C./min, and a vacuum oxygen partial pressure less than 2×10⁻³ Pa; and

cooling to a room temperature, to obtain the environmental barrier coating on the surface of the substrate.

### Embodiment 4

The method for coating an environmental barrier coating provided by this embodiment includes the following operating steps:

preparing a Si coating, a mullite coating, and a Yb₂SiO₅ coating on the surface of silicon carbide-based composite substrate by using air plasma spraying, with the coatings successively having thicknesses of 50 μm, 50 μm and 80 μm;

preparing an aluminum film layer with a thickness of 2 μm on the surface of the Yb₂SiO₅ coating by using the magnetron sputtering, wherein the conditions of the magnetron sputtering are as follows: a magnetron target current of 3 A and a bias voltage of 250 V;

heat treating the Yb₂SiO₅ coating deposited with the aluminum film layer, wherein the conditions of heat treatment are as follows: 800° C. kept for 2 h, 1350° C. kept for 20 h, a temperature raising rate of 5° C./min, and a vacuum oxygen partial pressure less than 2×10⁻³ Pa; and

cooling to a room temperature, to obtain the environmental barrier coating on the surface of the substrate.

### Embodiment 5

The method for coating an environmental barrier coating provided by this embodiment includes the following operating steps:

preparing a Si coating, a mullite coating, and a Yb₂SiO₅ coating on the surface of silicon carbide-based composite substrate by using plasma spraying-physical vapor deposition, with the coatings successively having thicknesses of 50 μm, 50 μm and 80 μm;

preparing an aluminum film layer with a thickness of 5 μm on the surface of the Yb₂SiO₅ coating by using the magnetron sputtering, wherein the conditions of the magnetron sputtering are as follows: a magnetron target current of 4 A and a bias voltage of 230 V;

heat treating the Yb₂SiO₅ coating deposited with the aluminum film layer, wherein the conditions of heat treatment are as follows: 800° C. kept for 4 h, 1350° C. kept for 24 h, a temperature raising rate of 10° C./min, and a vacuum oxygen partial pressure less than 2×10⁻³ Pa; and

cooling to a room temperature, to obtain the environmental barrier coating on the surface of the substrate.

### Embodiment 6

The method for coating an environmental barrier coating provided by this embodiment includes the following operating steps:

preparing a Si coating, a mullite coating, and a Yb₂SiO₅ coating on the surface of silicon carbide-based composite substrate by using air plasma spraying, with the coatings successively having thicknesses of 50 μm, 50 μm and 80 μm;

preparing an aluminum film layer with a thickness of 5 μm on the surface of the Yb₂SiO₅ coating by using the magnetron sputtering, wherein the conditions of the magnetron sputtering are as follows: a magnetron target current of 4 A and a bias voltage of 200 V;

heat treating the Yb₂SiO₅ coating deposited with the aluminum film layer, wherein the conditions of heat treatment are as follows: 800° C. kept for 4 h, 1350° C. kept for 24 h, a temperature raising rate of 5° C./min, and a vacuum oxygen partial pressure less than 2×10⁻³ Pa; and

cooling to a room temperature, to obtain the environmental barrier coating on the surface of the substrate.

### Embodiment 7

The method for coating an environmental barrier coating provided by this embodiment includes the following operating steps:

preparing a Si coating, a mullite coating, and a Yb₂SiO₅ coating on the surface of silicon carbide-based composite substrate by using air plasma spraying, with the coatings successively having thicknesses of 40 μm, 80 μm and 100 μm;

preparing an aluminum film layer with a thickness of 4 μm on the surface of the Yb₂SiO₅ coating by using the magnetron sputtering, wherein the conditions of the magnetron sputtering are as follows: a magnetron target current of 5 A and a bias voltage of 170 V;

heat treating the Yb₂SiO₅ coating deposited with the aluminum film layer, wherein the conditions of heat treatment are as follows: 750° C. kept for 3 h, 1320° C. kept for 22 h, a temperature raising rate of 30° C./min, and a vacuum oxygen partial pressure less than 2×10⁻³ Pa; and

cooling to a room temperature, to obtain the environmental barrier coating on the surface of the substrate.

### Embodiment 8

The method for coating an environmental barrier coating provided by this embodiment includes the following operating steps:

preparing a Si coating, a mullite coating, and a Yb₂SiO₅ coating on the surface of silicon carbide-based composite substrate by using air plasma spraying, with the coatings successively having thicknesses of 60 μm, 70 μm and 90 μm;

preparing an aluminum film layer with a thickness of 4 μm on the surface of the Yb₂SiO₅ coating by using the magnetron sputtering, wherein the conditions of the magnetron sputtering are as follows: a magnetron target current of 4 A and a bias voltage of 170 V;

heat treating the Yb₂SiO₅ coating deposited with the aluminum film layer, wherein the conditions of heat treatment are as follows: 720° C. kept for 3 h, 1320° C. kept for 23 h, a temperature raising rate of 20° C./min, and a vacuum oxygen partial pressure less than 2×10⁻³ Pa; and

cooling to a room temperature, to obtain the environmental barrier coating on the surface of the substrate.

### Embodiment 9

The method for coating an environmental barrier coating provided by this embodiment includes the following operating steps:

preparing a Si coating, a mullite coating, and a Yb₂SiO₅ coating on the surface of silicon carbide-based composite substrate by using air plasma spraying, with the coatings successively having thicknesses of 60 μtm, 60 μm and 90 μm;

preparing an aluminum film layer with a thickness of 3 μm on the surface of the Yb₂SiO₅ coating by using the magnetron sputtering, wherein the conditions of the magnetron sputtering are as follows: a magnetron target current of 4 A and a bias voltage of 170 V;

heat treating the Yb₂SiO₅ coating deposited with the aluminum film layer, wherein the conditions of heat treatment are as follows: 720° C. kept for 3 h, 1320° C. kept for 23 h, a temperature raising rate of 25° C./min, and a vacuum oxygen partial pressure less than 2×10⁻³ Pa; and

cooling to a room temperature, to obtain the environmental barrier coating on the surface of the substrate.

### EXPERIMENTAL EXAMPLE 1

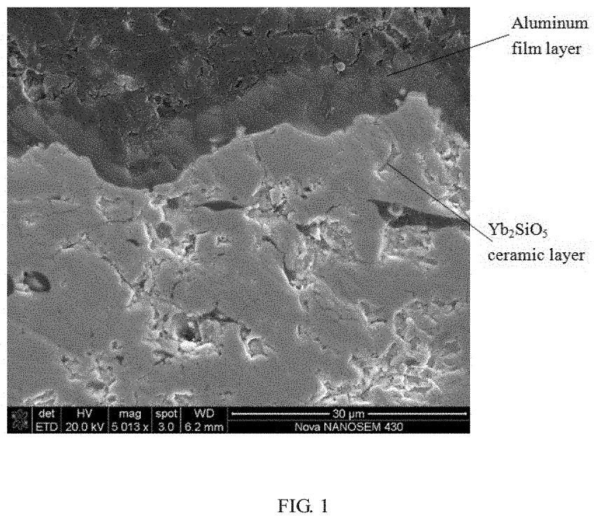

The coating, obtained after the aluminum film layer is coated and before the vacuum heat treatment is performed in the preparing process of Embodiment 1 was cut, the section after the cutting was polished, and then subjected to a scanning electron microscope to obtain a microstructure diagram as shown in FIG. 1.

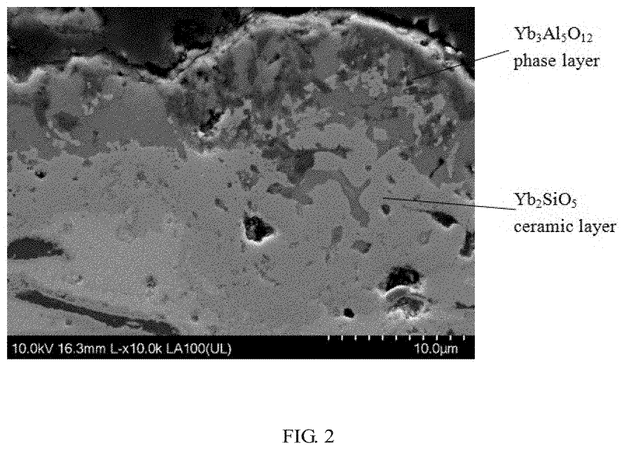

The final coating prepared in Embodiment 1 was cut, and the section after the cutting was polished and then subjected to a scanning electron microscope to obtain a microstructure diagram as shown in FIG. 2.

It can be seen from FIG. 1 that there are pores in the Yb₂SiO₅ ceramic layer.

It can be seen from FIG. 2 that the pores on the surface of the Yb₂SiO₅ ceramic layer are filled with Yb₃Al₅O₁₂ after the heat treatment.

To sum up, for the method for coating an environmental barrier coating provided by the present disclosure, since an aluminum film layer is provided on the surface of the rare earth silicate and then heat treatment is performed, molten aluminum enters the pores on the surface of the rare earth silicate ceramic layer to fill the pores, and the molten aluminum reacts with the rare earth oxide and silicon dioxide to form a more dense and water-resistant rare earth aluminate, with the rare earth oxide and silicon dioxide generated by the decomposition of the rare earth silicate ceramic layer under the thermal environment. The present disclosure effectively improves the service performance of the environmental barrier coating and prolongs the service time thereof.

Further, in addition to enabling the rare earth aluminate phase to be generated in the pores on the surface of the rare earth silicate ceramic layer, the heat treatment also enables the rare earth aluminate phase layer to be formed on the surface of the rare earth silicate ceramic layer, which can further improve the performance of the environmental barrier coating.

Further, when the rare earth silicate is Yb₂SiO₅, heat treatment is performed at an appropriate temperature to generate Yb₃Al₅O₁₂, which has good thermal compatibility with Yb₂SiO₅. The Yb₃Al₅O₁₂ layer has relatively high strength and fracture toughness and low heat conductivity coefficient, which can make the obtained environmental barrier coating have the characteristics of high density and excellent resistance to water and oxygen corrosion. Performing heat treatment on the aluminum film layer to form the Yb₃Al₅O₁₂ coating effectively avoids the defects of large stress cracks produced during the thermal spraying process, and enables the Yb₃Al₅O₁₂ coating to be effectively used in the field of high-temperature protective coatings.

Since the environmental barrier coating provided by the present disclosure is prepared by the method provided by the present disclosure, it has a dense and water-resistant rare earth aluminate phase layer on its surface, and the pores on the outward side of the ceramic layer containing the rare earth silicate are also filled, therefore, the environmental barrier coating has good service performance and long service life.

The above mentioned are only preferred embodiments of the present disclosure, and are not intended to limit the present disclosure. For those skilled in the art, various modifications and changes can be made to the present disclosure. Any modifications, equivalent replacements, and improvements made within the spirit and principle of the present disclosure shall be included in the protection scope of the present disclosure.

### INDUSTRIAL APPLICABILITY

For the method for coating an environmental barrier coating provided by the present disclosure, since an aluminum film layer is provided on the surface of the rare earth silicate and then heat treatment is performed, molten aluminum enters the pores on the surface of the rare earth silicate ceramic layer to fill the pores, and the molten aluminum reacts with the rare earth oxide and silicon dioxide to form a more dense and water-resistant rare earth aluminate phase, with the rare earth oxide and silicon dioxide generated by the decomposition of the rare earth silicate ceramic layer under the thermal environment. The present disclosure effectively improves the service performance of the environmental barrier coating and prolongs the service time thereof.

For the environmental barrier coating provided by the present disclosure, since it is prepared by using the method provided by the present disclosure, it has good service performance and long service time. When used in the aerospace field, it can significantly improve the service performance and service life of the aerospace equipment.

What is claimed is:

1. A method for coating an environmental barrier coating, comprising:
coating an aluminum film layer on a surface of a rare earth silicate ceramic layer formed by thermal spraying; and
heat treating the aluminum film layer to form a rare earth aluminate phase at least in pores of a side of the rare earth silicate ceramic layer facing the aluminum film layer.

2. The method for coating an environmental barrier coating according to claim 1, wherein the aluminum film layer has a thickness of 2-5 μm.

3. The method for coating an environmental barrier coating according to claim 2, wherein the aluminum film layer is coated by a magnetron sputtering method.

4. The method for coating an environmental barrier coating according to claim 1, wherein the rare earth silicate ceramic layer is selected from the group consisting of a Lu₂Si₂O₇ ceramic layer, a Lu₂SiO₅ ceramic layer, a Yb₂SiO₅ ceramic layer and a Yb₂SiO₅ ceramic layer.

5. The method for coating an environmental barrier coating according to claim 4, wherein the heat treating is performed by holding at a temperature of 700-800° C. for 2-4 h, and then raising the temperature to 1300-1350° C. and holding for 20-24 h.

6. The method for coating an environmental barrier coating according to claim 5, wherein the temperature is raised at a rate of 5-30° C./min.

7. The method for coating an environmental barrier coating according to claim 1, wherein before the coating an aluminum film layer on a surface of a rare earth silicate ceramic layer, the method further comprises:
coating the rare earth silicate ceramic layer on a surface of a mullite layer.

8. The method for coating an environmental barrier coating according to claim 7, wherein before the coating the rare earth silicate ceramic layer on a surface of a mullite layer, the method further comprises:
coating the mullite layer on a surface of a silicon layer.

9. An environmental barrier coating, wherein the environmental barrier coating is obtained by using the method for coating an environmental barrier coating according to claim 1.

10. The method for coating an environmental barrier coating according to claim 1, wherein the aluminum film layer is heat-treated to form the rare earth aluminate phase in the pores on the side of the rare earth silicate ceramic layer facing the aluminum film layer, and to form a rare earth aluminate phase layer on the side of the rare earth silicate ceramic layer facing the aluminum film layer.

11. The method for coating an environmental barrier coating according to claim 3, wherein operating parameters of the magnetron sputtering method comprise: a magnetron target current of 3-6 A, and a bias voltage of 150-250 V.

12. The method for coating an environmental barrier coating according to claim 4, wherein the rare earth silicate ceramic layer is the Yb₂SiO₅ ceramic layer, and a Yb₃Al₅O₁₂ coating is formed after heat treating the surface on which the aluminum film layer is deposited.

13. The method for coating an environmental barrier coating according to claim 5, wherein the heat treatment is a vacuum heat treatment, in which an oxygen partial pressure is less than 2×10⁻³ Pa.

14. The method for coating an environmental barrier coating according to claim 7, wherein the surface of the mullite layer is coated with the rare earth silicate ceramic layer by using an air plasma spraying method or a plasma spraying-physical vapor deposition method.

15. The method for coating an environmental barrier coating according to claim 7, wherein the mullite layer has a thickness of 50-80 μm; and the rare earth silicate ceramic layer has a thickness of 80-100 μm.

16. The method for coating an environmental barrier coating according to claim 8, wherein the silicon layer has a thickness of 40-60 μm.

17. The method for coating an environmental barrier coating according to claim 8, wherein the surface of the silicon layer is coated with the mullite layer by using an air plasma spraying method or a plasma spraying-physical vapor deposition method.

18. The method for coating an environmental barrier coating according to claim 8, wherein before the coating the mullite layer on a surface of a silicon layer, the method further comprises:
coating the silicon layer on a surface of a substrate.

19. The method for coating an environmental barrier coating according to claim 18, wherein the surface of the substrate is coated with the silicon layer by using an air plasma spraying method or a plasma spraying-physical vapor deposition method.

20. The method for coating an environmental barrier coating according to claim 18, wherein the substrate is a silicon carbide-based composite substrate.
